(19) United States
(12) Patent Application Publication
(10) Pub. No.: US 2014/0077668 A1
(43) Pub. Date: Mar. 20, 2014

(54) FRICTION STIR WELDING PARTS INCLUDING ONE OR MORE EXPENDABLE PORTIONS

(71) Applicants: David J. MORGENSTERN, Palo Alto, CA (US); Collin D. CHAN, San Jose, CA (US); Daniel M. SULLIVAN, Sunnyvale, CA (US)

(72) Inventors: David J. MORGENSTERN, Palo Alto, CA (US); Collin D. CHAN, San Jose, CA (US); Daniel M. SULLIVAN, Sunnyvale, CA (US)

(73) Assignee: Apple Inc., Cupertino, CA (US)

(21) Appl. No.: 13/620,109

(22) Filed: Sep. 14, 2012

(51) Int. Cl. B23K 20/12; H05K 5/02; H05K 13/00; B23K 31/02

(52) U.S. Cl. CPC B23K 20/122; B23K 20/1245; B23K 31/02; H05K 5/0226; H05K 13/00
USPC 312/223.1; 228/112.1; 228/114; 228/2.1; 29/428

(57) ABSTRACT

A method for friction stir welding is provided. The method may include compressing mating surfaces of first and second parts against one another in a fixture. One of the first part and the second part may include a first expendable portion and one of the first part and the second part may include a second expendable portion. A rotating pin may be inserted into the first expendable portion, directed along the joint, and removed from the second expendable portion. A conical pin with a threaded outer surface comprising one or more flat sections may be employed in the welding operations.

### TECHNICAL FIELD

The present disclosure relates generally to friction stir welding, and more particularly to methods and apparatuses for improving the quality of welds produced by friction stir welding.

### BACKGROUND

Various types of methods and apparatuses have been developed for joining two parts. Example embodiments of methods for joining two parts include adhesive bonding, welding, use of fasteners, etc. In the context of joining certain materials, such as metals, welding has been identified as a suitable method presently in use today.

Various forms of welding methods exist. Example embodiments of welding methods include laser welding, arc welding, gas welding, and friction stir welding. Friction stir welding may present certain advantages over other forms of welding. For example, friction stir welding may not involve heating the parts being welded to as great of an extent as other forms of welding. Further, friction stir welding may not require use of flux or gases which could introduce contaminants into the weld. However, friction stir welding may present issues that may make friction stir welding undesirable for certain applications.

Accordingly, apparatuses and methods for improved friction stir welding are provided.

### SUMMARY

A method for friction stir welding is provided. The method may include positioning first and second parts in a fixture with mating surfaces thereof contacting one another. The first part and the second part may be compressed together in the fixture. A rotating pin may be inserted into a first expendable portion defined by one of the first part and the second part. The rotating pin may then be directed along the joint between the first and second parts to joint the two parts by intermixing the materials thereof. The rotating pin may be removed from a second expendable portion defined by one of the first and second parts. Accordingly, any open holes created at the location where the rotating pin is inserted into or removed from the material are defined in the expendable portions. The expendable portions may be removed, for example by machining off the expandable portions. Thus, the resulting weld may be free of open holes or other distortions that may occur where a rotating pin is inserted or removed.

A tool configured for friction stir welding is also provided. The tool may be employed to conduct the above-described operations, although various other embodiments of tools may be employed in other embodiments. The tool may include a shoe and a conical pin with a threaded outer surface. One or more flat sections may be provided on the tool. This configuration may assist in intermixing the materials defining two parts being welded together.

An enclosure for an electronic device formed in accordance with the operations described above and a non-transitory computer readable medium for storing instructions configured to control a friction stir welding system are also provided.

Other apparatuses, methods, features and advantages of the disclosure will be or will become apparent to one with skill in the art upon examination of the following figures and detailed description. It is intended that all such additional systems, methods, features and advantages be included within this description, be within the scope of the disclosure, and be protected by the accompanying claims.

### BRIEF DESCRIPTION OF THE DRAWINGS

The included drawings are for illustrative purposes and serve only to provide examples of possible structures and arrangements for the disclosed assemblies, methods, and systems. These drawings in no way limit any changes in form and detail that may be made to the disclosure by one skilled in the art without departing from the spirit and scope of the disclosure.

FIG. 1 illustrates a perspective view of operations performed in friction stir welding;

FIG. 2 illustrates a schematic view of a system for friction stir welding according to an example embodiment of the present disclosure;

FIG. 3 illustrates a side view of a tool configured for friction stir welding according to an example embodiment of the present disclosure;

FIG. 4 illustrates an end view of the tool configured for friction stir welding of FIG. 3;

FIG. 5 illustrates a side view of an electronic device including an enclosure that may be formed by friction stir welding according to an example embodiment of the present disclosure;

FIG. 6 illustrates an inverted front view of a housing prior to joining with a base member to define the enclosure of FIG. 5 according to an example embodiment of the present disclosure;

FIG. 7 illustrates a side view of the housing of FIG. 6, a base member, and a fixture prior to coupling therebetween according to an example embodiment of the present disclosure;

FIG. 8 illustrates a side view of the housing, base member, and fixture of FIG. 7 after coupling therebetween according to an example embodiment of the present disclosure;

FIG. 9 illustrates a front view of the housing and the base member of FIG. 7 during friction stir welding operations performed thereon to form the enclosure of FIG. 5, with the fixture not shown for clarity purposes, according to an example embodiment of the present disclosure;

FIG. 10 illustrates a perspective view of machining operations performed on the base member and the housing of FIG. 7 after friction stir welding according to an example embodiment of the present disclosure;

FIG. 11 illustrates a method for friction stir welding according to an example embodiment of the present disclosure; and

FIG. 12 illustrates a block diagram of an electronic device according to an example embodiment of the present disclosure.

### DETAILED DESCRIPTION

Exemplary applications of apparatuses, systems, and methods according to the present disclosure are described in this section. These examples are being provided solely to add context and aid in the understanding of the disclosure. It will thus be apparent to one skilled in the art that the present disclosure may be practiced without some or all of these specific details. In other instances, well known process steps have not been described in detail in order to avoid unnecessarily obscuring the present disclosure. Other applications are possible, such that the following examples should not be taken as limiting.

Friction stir welding is a method for joining two parts which may present certain advantages over other forms of welding. For example, friction stir welding may not heat the parts being welded to as great of an extent as other forms of welding. In this regard, certain materials may not be able to withstand temperatures associated with other forms of welding. Further, subjecting the parts to high heat may cause the parts to warp. Stresses may also build at the joint as a result of the heat that may eventually lead to failure of the weld.

Additionally, friction stir welding be advantageous in that it may not require use of flux or gases which could introduce contaminants into the weld. Introduction of contaminants into the weld may affect other operations later performed on the parts. For example, it may be more difficult to anodize the parts when contaminants have been introduced into the weld.

Friction-stir welding is a solid-state joining process (meaning the metal is not melted) and may be used in applications where the original metal characteristics must remain unchanged as far as possible. Friction stir welding function by mechanically intermixing the two pieces of metal at the place of the joint, transforming them into a softened state that allows the metal to be fused using mechanical pressure. This process is primarily used on aluminum, although other materials may be welded, and is most often used on large pieces which cannot be easily heat treated post weld to recover temper characteristics.

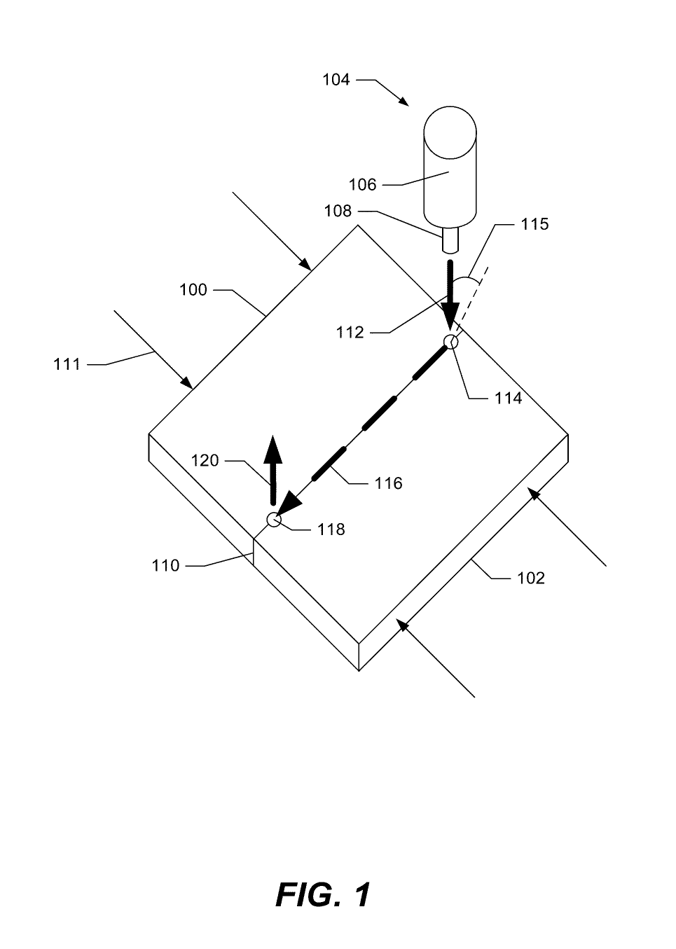

FIG. 1 schematically illustrates an example embodiment of the friction stir welding process. As illustrated, a first part 100 can be joined to a second part 102 via friction stir welding using a constantly rotated tool 104 including a shoe 106 and a pin 108 extending therefrom. In order to weld the first part 100 and the second part 102 together along a joint 110 therebetween, a compressive force may be applied which clamps the parts 100, 102 together along the joint 110, as indicated by the arrows 111. The compressive force may be applied to the parts 100, 102 throughout the friction stir welding process. The parts 100, 102 may be positioned and clamped such that they are substantially aligned in a coplanar configuration as illustrated, although various other embodiments of joints may be employed.

The rotating tool 104 may initially be inserted into the joint 110 by directing the tool downwardly along a path 112 at a starting point 114. Thereafter, the tool 104 may be tilted backwardly by an angle 115. The backwardly-tilted tool 104 may then be transversely fed along a path 116 along the joint 110 between the first part 100 and the second part 102, which may be clamped together as noted above. The pin 108 may be slightly shorter than the weld depth required, with the shoe 106 riding atop the work surface.

Frictional heat is generated between the wear-resistant welding components defining the tool 104 and the work pieces. This heat, along with that generated by the mechanical mixing process and the adiabatic heat within the material, cause the stirred materials to soften without melting. As the pin 108 is moved forward along the path 116 the plasticized material moves to the rear where clamping force assists in a forged consolidation the weld. This process of the tool 104 traversing along the weld line in a plasticized tubular shaft of material may result in severe solid state deformation involving dynamic recrystallization of the base material. After traversing the path 116 at the joint 110, the tool 104 may be lifted from the material at an end point 118 upwardly along a path 120. Accordingly, a weld may be created along the joint 110 between the start point 114 and the end point 118.

However, friction stir welding may present certain issues that may make friction stir welding undesirable in some circumstances. In this regard, certain defects may exist in the weld. For example, an open hole may exist at the start point 114 and/or the end point 118. Thus, friction stir welding may produce welds which are cosmetically unappealing at one or both of the ends thereof.

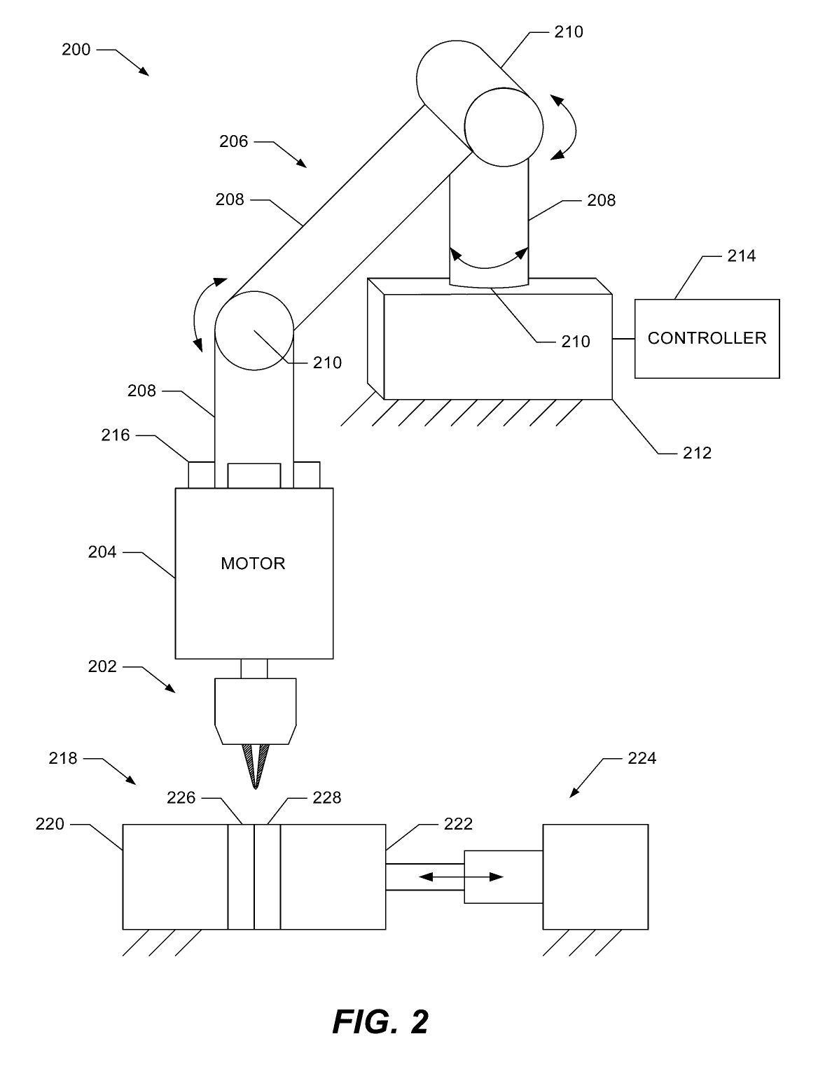

Accordingly, embodiments of the disclosure are configured to improve the quality of welds produced by friction stir welding, for example by improving the appearance thereof. In this regard, FIG. 2 illustrates a friction stir welding system 200 according to an embodiment of the present disclosure. The friction stir welding system 200 may include a tool 202, which may be rotated by a motor 204. The position of the motor 204 and the tool 202 may be controlled by a robotic assembly 206. The robotic assembly 206 may include one or more arms 208, one or more joints 210, and a base 212. Thus, the arms 208 may be rotated about the joints 210 to position the tool 202 at an appropriate position to friction stir weld. However, various other embodiments of robotic assemblies (e.g., gantry systems) may be employed to control the position of the tool 202. Regardless of the particular embodiment of robotic assembly employed, the friction stir welding system 200 may further comprise a controller 214. The controller 214 may be configured to control the robotic assembly 206, the motor 204, and/or or other portions of the friction stir welding system 200.

In some embodiments the friction stir welding system 200 may further comprise one or more load cells 216. The load cells 216 may be configured to detect load applied to the friction stir welding system 200. For example, during operation of the friction stir welding system 200, the tool 202 may tend to veer off course from the joint between the two parts being welded as a result of torque applied to the tool. Accordingly, the load sensors 216, which may be equally distributed around the motor 204 and/or one of the arms 208 of the robotic assembly 206, may detect the load applied by the torque and the controller 214 may instruct the robotic assembly to compensate therefor to prevent the tool 202 from veering away from the joint. Thus, a weld that closely follows the joint may be formed.

As illustrated in FIG. 2, in some embodiments the friction stir welding system 200 may further comprise a fixture 218. In some embodiments the fixture 218 may comprise a first fixture portion 220 and a second fixture portion 222. Further, an actuator 224 (e.g., a hydraulic or pneumatic piston and cylinder) may be configured to compress the first fixture portion 220 relative to the second fixture portion 222. Accordingly, the fixture 218 may compress a first part 226 against a second part 228 such that the tool 202 may weld the first part and the second part together.

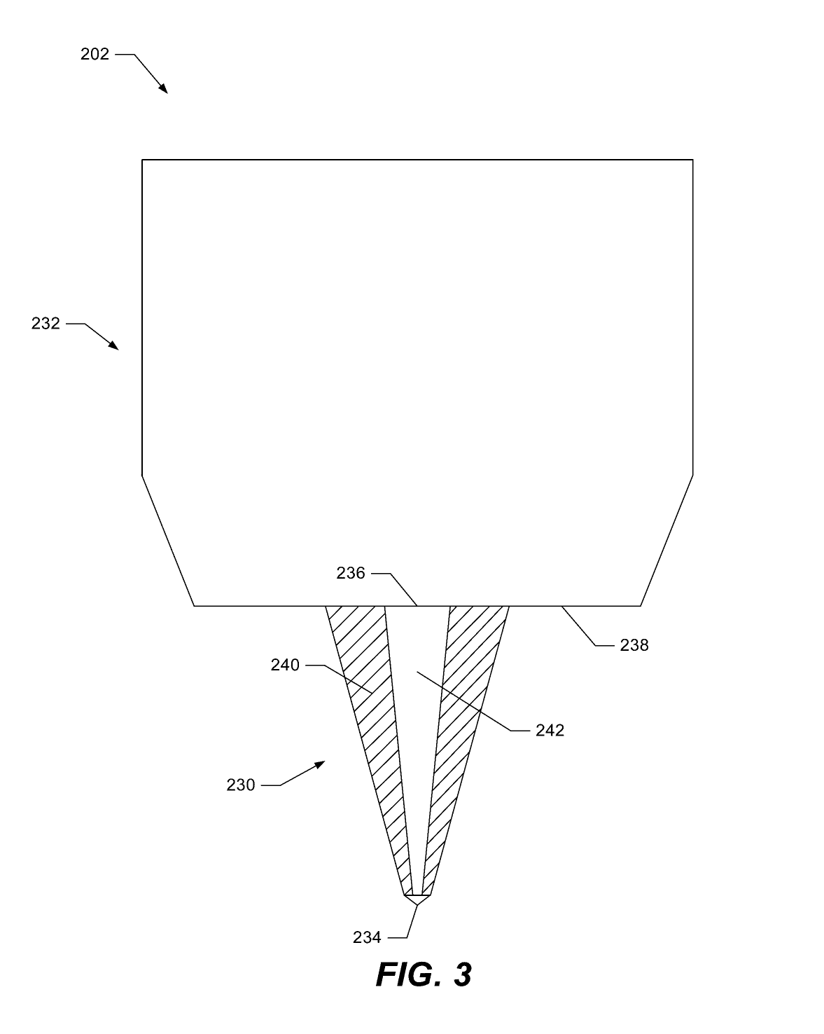

FIG. 3 illustrates an enlarged side view of the tool 202 configured for friction stir welding. The tool 202 may be configured to improve mixing of the material defining a first part and a second part that are being welded. As illustrated, the tool 202 may include a conical pin 230 and a shoe 232. The conical pin 230 may extend between a first end 234 and a second end 236. The conical pin 230 may be truncated at the first end 234 such that the conical pin 230 does not extend to a point at the first end. In one example embodiment of the conical pin 230 configured to improve the operation thereof, the first end 234 may define a diameter between about 0.5 mm and 3 mm (e.g., about 1 mm), and the second end 236 may define a diameter between about 5 mm and 9 mm (e.g., about 7 mm). In another embodiment the conical pin 230 may extend to a point at the first end 234, as illustrated, which may improve operation of the conical pin relative to a blunt tipped embodiment.

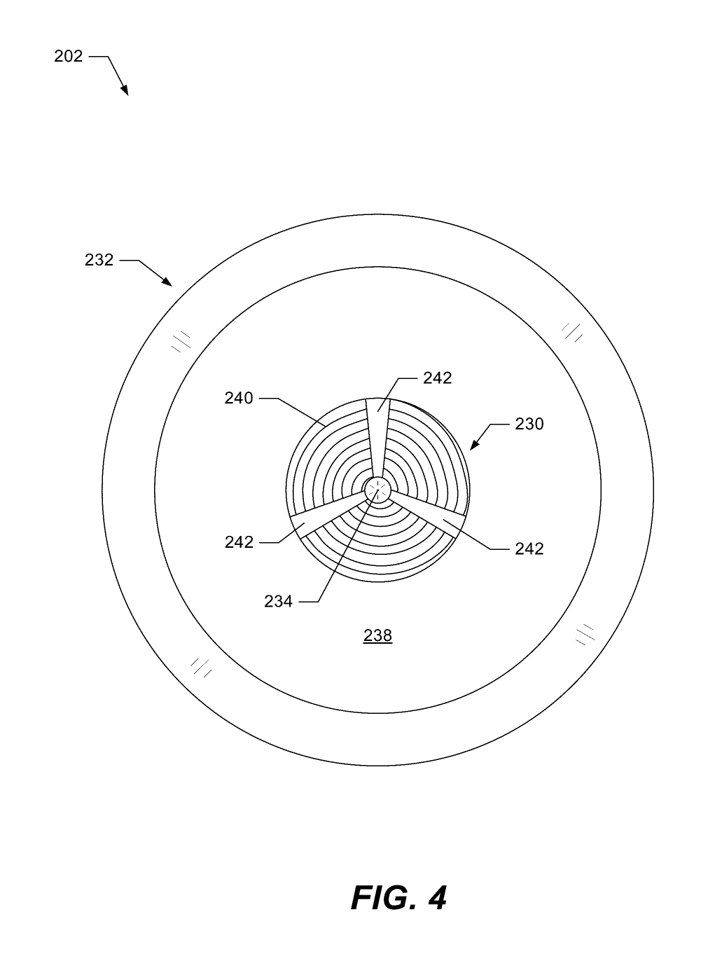

The shoe 232 may define a planar shoulder 238 proximate the second end 236 of the conical pin 230. The planar shoulder 238 may be configured to ride atop the surface of the joint. Further, the conical pin 230 may define a threaded outer surface 240 comprising one or more flat sections 242, which may extend between the first end 234 and the second end 236. As illustrated in FIG. 4, which is an end view of the tool 202 directed toward the first end 234, in some embodiments the conical pin 230 may comprise three flat sections 242, which may be equally spaced around the circumference of the threaded outer surface 238.

As the conical pin 230 rotates, the materials defining the first part and the second part being welded may intermix. More particularly, the conical shape of the conical pin 230, the threaded outer surface 240, and the flat sections 242 may function to draw the materials up against the planar shoulder 238 of the shoe 232 and then back down while intermixing the plasticized materials. Accordingly, the embodiment of the tool 202 illustrated in FIGS. 2-4 may provide for improved intermixing between the materials defining the parts being welded. Thus, an improved weld may be formed.

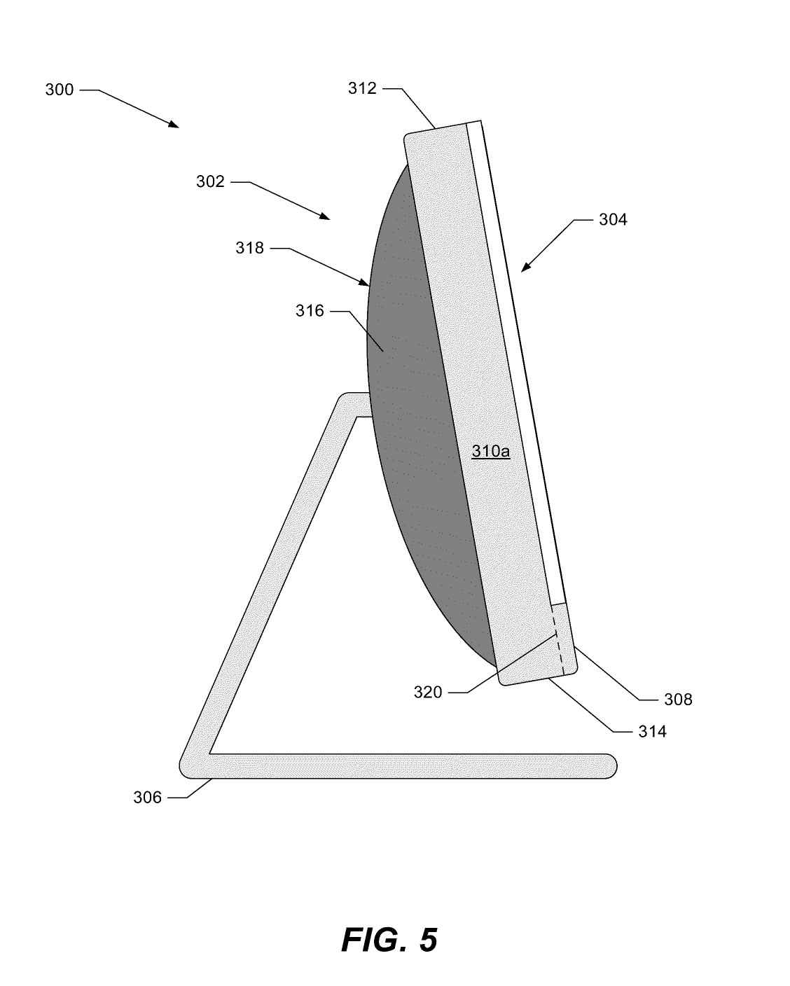

Friction stir welding may be employed to weld a variety of different parts comprising a number of different materials to form various assemblies. However in one example embodiment, as illustrated in FIG. 5, an electronic device 300 may include an enclosure 302 formed from friction stir welding. More particularly, the electronic device may comprise a computing device having an oversized display screen presentation utilizing a display screen to housing interface. The electronic device 300 may include a display cover 304 disposed with respect to the enclosure 302. The display cover 304 is preferably placed proximate to and in front of a display device that is enclosed within the enclosure 302. The enclosure 302 may also enclose various other computer components, such as a microprocessor (not shown) coupled to the display device, as well as one or more memory or storage units, speakers, additional displays or indicators, buttons or other input devices, video cards, sound cards, power inlets, various ports, and the like. Alternatively, the depicted electronic device 300 may only include a monitor, terminal or other simple display unit, with any associated processors or other computing components being located away from the depicted display device.

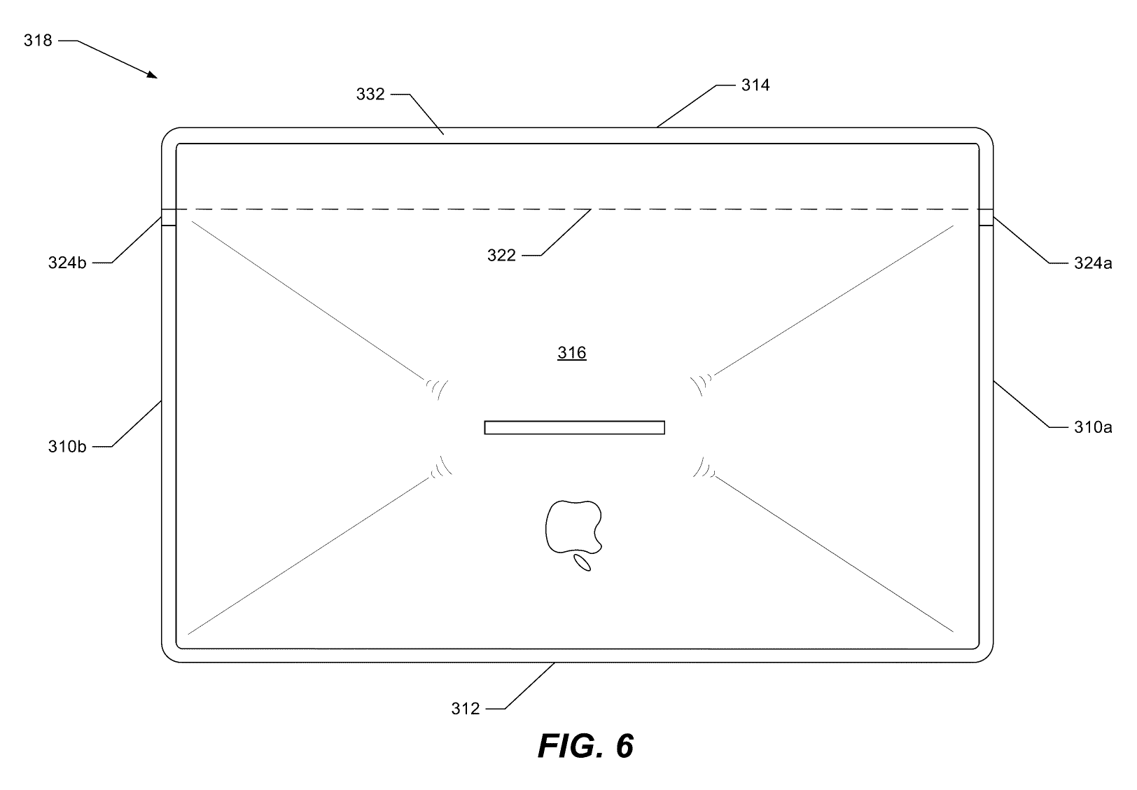

A stand 306 or other similar structure can be used to support the entire electronic device 300. Further, the enclosure 302 may have a frontally offset bottom chin portion or region referred to herein as a base member 308 that borders a bottom side edge of the display cover 304. In addition, the enclosure 302 can also include first and second sidewalls 310a, b (see, e.g., FIG. 6), a top wall 312, and a bottom wall 314 that extend backwards from the front face of electronic device 300, as well as a back wall 316. The back wall 316 may have some amount of curvature to it in various directions, and the enclosure 302 may form a single integrated housing 318 including the sidewalls 310a, b, the top wall 312, the bottom wall 314, and the back wall 316, as will be readily appreciated.

However, the base member 308 may be a separate component that is attached to the sidewalls 310a, b and the bottom wall 314 along a line 320 to form the enclosure 302. In this regard, for example, the base member 308 may be friction stir welded to the housing 318 at the sidewalls 310a, b and the bottom wall 314. Accordingly, in one example embodiment, the base member 308 may be attached to the housing 318 by welding along three edges of the base member at the first and second sidewalls 310a, b and the bottom wall 314.

FIG. 6 illustrates a view of the housing 318 prior to attachment of the base member 308. A line 322 illustrates the position at which an end of the base member 308 may be positioned upon attachment to the housing 318. As illustrated, the housing 318 may initially include one or more expendable portions 324a, b, which the base member 308 may abut against along line 322 when attached thereto. An expendable portion, as used herein, refers to a portion of one of the first part and the second part which may be removed without affecting the weld between the first part and the second part. In this regard, the expendable portion may be positioned past (e.g., away from or outside of) the joint. The expendable portions 324a, b may comprise removable tabs of material in some embodiments, as described below.

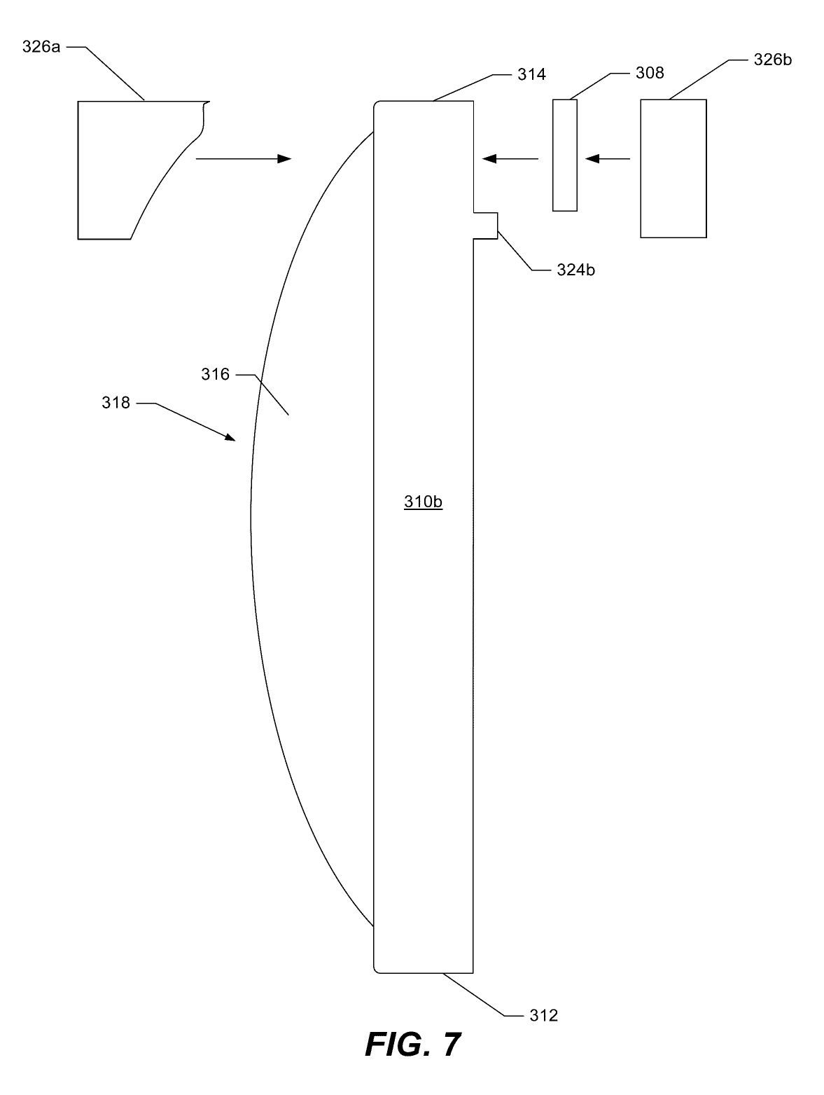

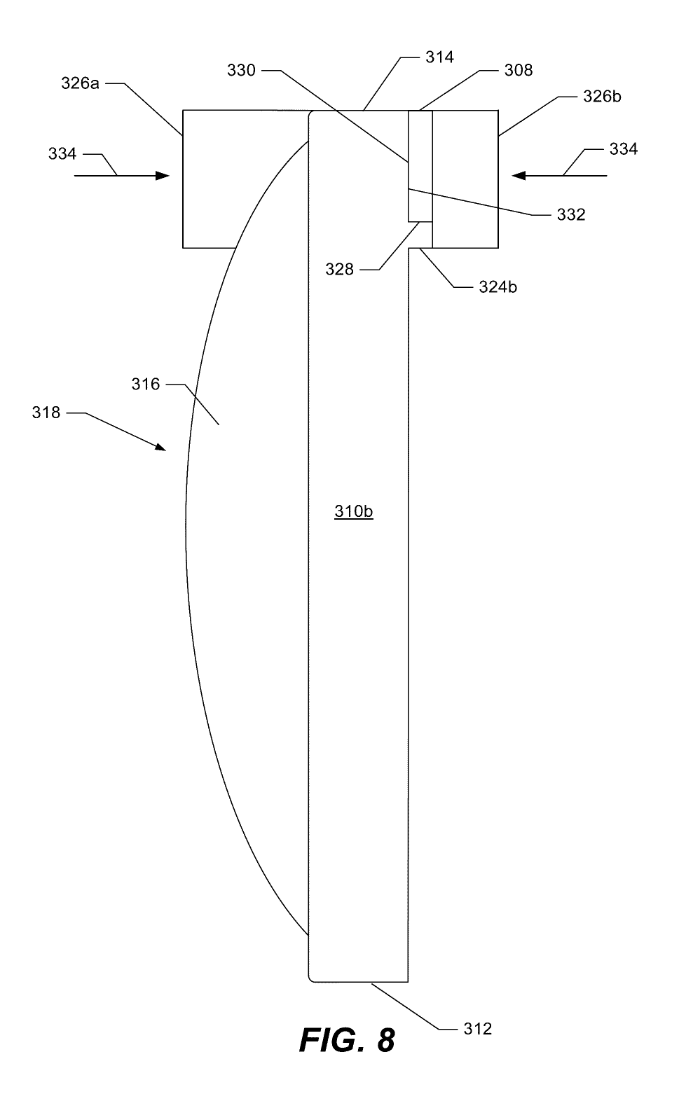

In this regard, FIG. 7 illustrates a side view of the housing 318 and the base member 308 prior to coupling therebetween. FIG. 7 further illustrates first and second portions 326a, b of a fixture (collectively, “326”) configured to hold the base member 308 and the housing 318 in place during welding operations. As illustrated in FIG. 8, the base member 308 may be positioned proximate the expendable portions 324a, b. For example, an edge 328 of the base member 308 may be in abutting contact with the expendable portions 324a, b. Further, a mating surface 330 of the base member 308 may be in abutting contact with a mating surface 332 of the housing 318 defined by the sidewalls 310a, b and the bottom wall 314 of the housing 302. The fixture 326 may compress the mating surfaces 330, 332 of the base member 308 and the housing 318 together, as illustrated by the arrows 334 to facilitate joining therebetween during the friction stir welding process, as described above.

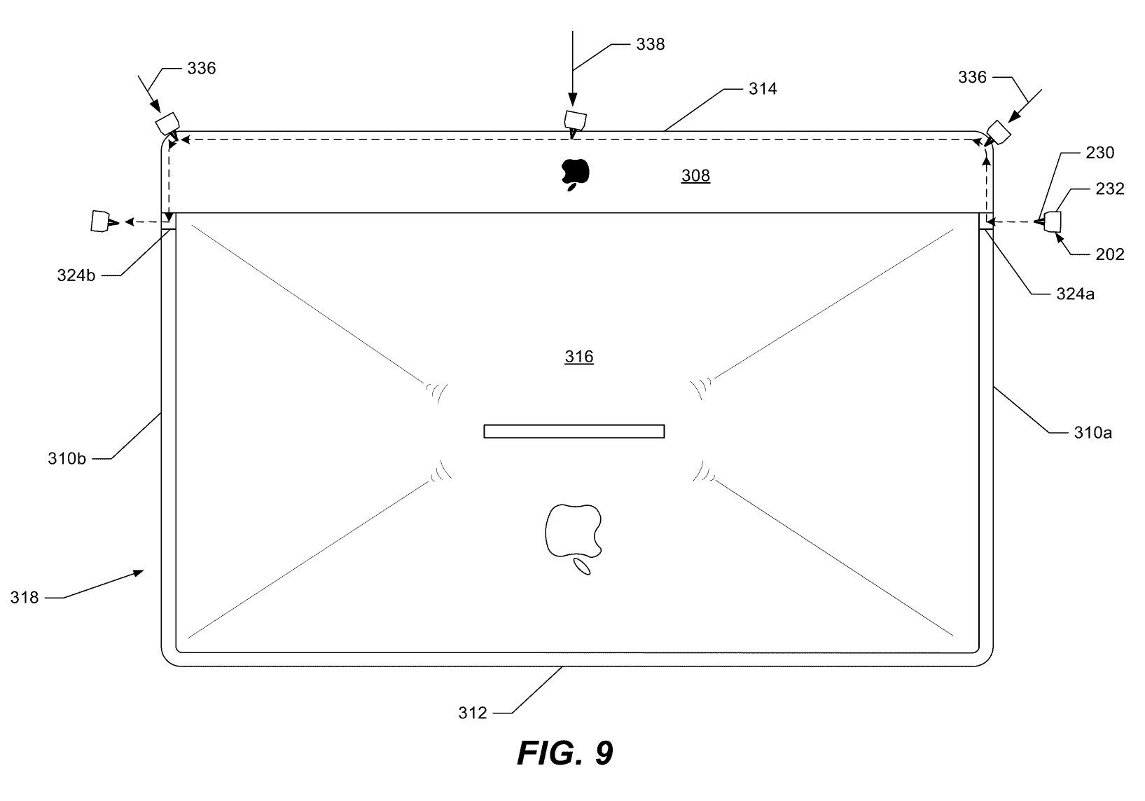

FIG. 9 illustrates the movement of the tool 202 during the friction stir welding process. Note that various other embodiments of the friction stir welding tools may be employed with the methods for friction stir welding with expendable portions and use of the tool 202 described above is provided for example purposes only. Further, in some embodiments the parts being friction stir welded may be preheated prior to being friction stir welded together. Preheating may reduce the thermal stresses on the parts being welded and improve the resulting weld.

As illustrated in FIG. 9, friction stir welding the base member 308 to the housing 318 may begin by inserting the rotating conical pin 230 into the first expendable portion 324a. In this regard, the rotating conical pin 230 may drill into the first expendable portion 324a. As noted above, the friction stir welding tool 202 may be tilted backward after insertion, and the base member 308 and the housing 318 may be clamped together during the friction stir welding process. The rotating conical pin 230 may then be directed out of the expendable portion 324a and along the joint between the base member 308 and the housing 318. A force may be applied between the rotating conical pin 230 along a rotational axis of the conical pin as the conical pin is directed along the joint between the base member 308 and the housing 318. As a result of applying force along the rotational axis of the conical pin 230, the shoe 232 of the tool 202 may ride along the surface of the base member 308 and the housing 318 at the joint.

As illustrated, in some embodiments the first part and the second part may define one or both of straight and curved surfaces at the joint therebetween. The force applied along the rotational axis of the conical pin 230 may be decreased when the rotating conical pin 230 is directed along a curved surface (see, e.g., forces 336) relative to the force (see, e.g., force 338) applied when directing the rotating pin along a straight surface. By reducing the force applied as the tool 202 is directed along curved surfaces, the pressure applied to the joint may be maintained substantially constant, because the planar shoulder of shoe 232 of the tool applies the force to the joint over a reduced surface area due to the curvature of the parts being welded.

Eventually, the rotating conical pin 230 will reach the end of the joint between the base member 308 and the housing 318 and enter into the second expendable portion 324b. Thus, the tool 202 may be removed from the second expendable portion 324b. As a result of initially inserting the rotating conical pin 230 into an expendable portion 324a and removing the rotating conical pin from an expendable portion 324b, issues with respect to leaving an open hole in the joint between the base member 308 and the housing 318 may be avoided. In this regard, the starting point and the end point for the friction stir welding are both positioned in the expendable portions 324a, b, rather in the joint between the base member 308 and the housing 318.

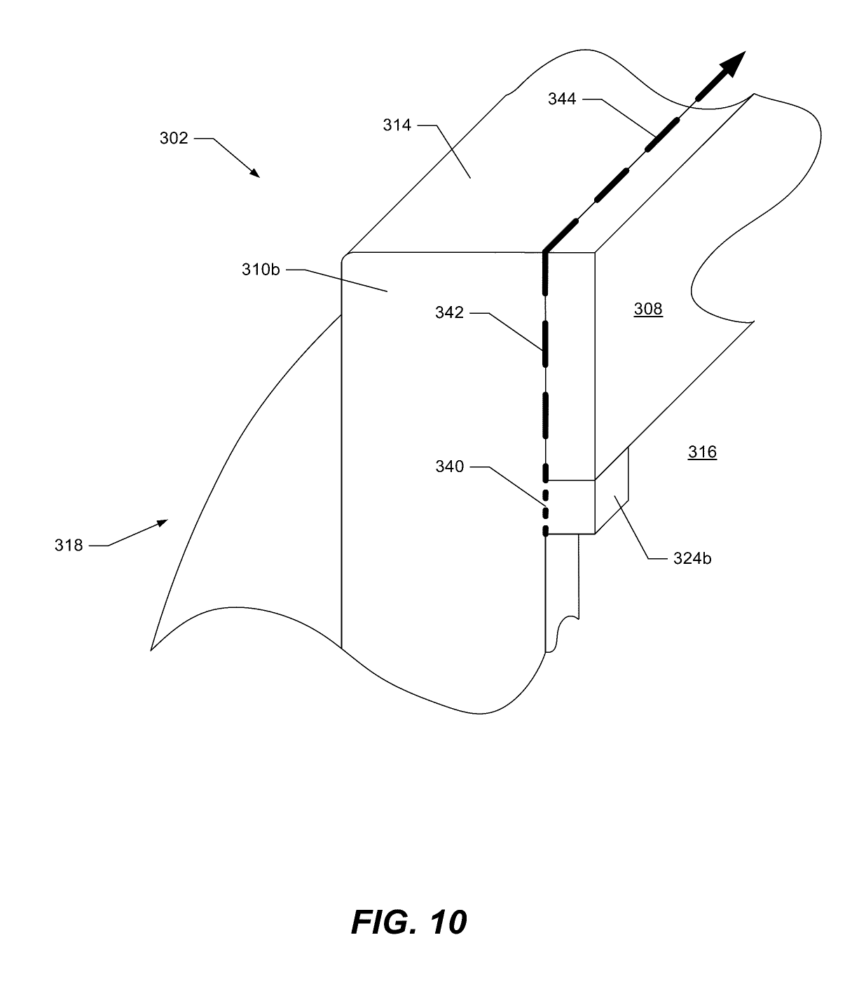

After the weld is completed in accordance with the above-described operations, in some embodiments the expendable portions 324a, 324b may be removed from the enclosure 302. For example, the expandable portions may be machined off from the remainder of the enclosure 302 along a line 340, as illustrated in FIG. 10. Since the conical pin 230 is inserted and removed from the expendable portion 324a, b, any resulting open holes may be removed from the enclosure 302 by removing the expendable portions. Accordingly, the appearance of the resulting weld may be improved.

Additional operations may be performed on the enclosure 302. For example, the enclosure 302 may be machined along welded surfaces at which the base member 308 and the housing 318 are joined, as indicated by lines 342 and 344, in order to form a smooth continuous surface. In some embodiments the enclosure 302 may also be anodized. In this regard, as noted above, the friction stir welding may not have a detrimental effect on the ability of the welded parts to be anodized.

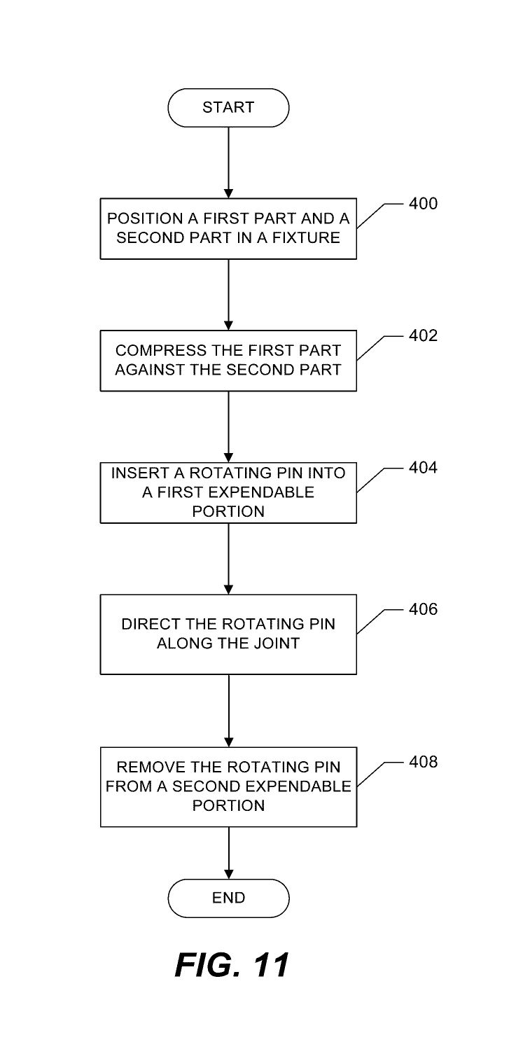

A related friction stir welding method is also provided. As illustrated in FIG. 11, the method may include positioning a first part and a second part in a fixture with a mating surface of the first part contacting a mating surface of the second part at a joint at operation 400. One of the first part and the second part may define a first expendable portion at a first end of the joint and one of the first part and the second part may define a second expendable portion at a second end of the joint. The method may further comprise compressing the mating surface of the first part against the mating surface of the second part at operation 402. Additionally, the method may include inserting a rotating pin into the first expendable portion at operation 404. The method may also include directing the rotating pin along the joint to join the first part to the second part and form an assembly at operation 406. Further, the method may include removing the rotating pin from the second expendable portion at operation 408.

In some embodiments the method may further comprise removing the first expendable portion and the second expendable portion. Removing the first expendable portion and the second expendable portion may comprise machining off the first expendable portion and the second expendable portion. The method may also include applying a force between the rotating pin and the joint along a rotational axis of the rotating pin. Directing the rotating pin along the joint may comprise directing the rotating pin along a curved surface and directing the rotating pin along a straight surface. Additionally, the method may include decreasing the force when directing the rotating pin along the curved surface relative to the force employed when directing the rotating pin along the straight surface. Also, the method may include tilting the tilting the rotating pin backwardly after inserting the rotating pin at operation 404 and prior to directing the rotating pin along the joint at operation 406.

Further, in some embodiments the method may include preheating the first part and the second part. The method may also include anodizing the assembly. The assembly may comprise an enclosure for an electronic device in some embodiments. Additionally, the rotating pin may comprise a conical pin defining a threaded outer surface comprising one or more flat sections.

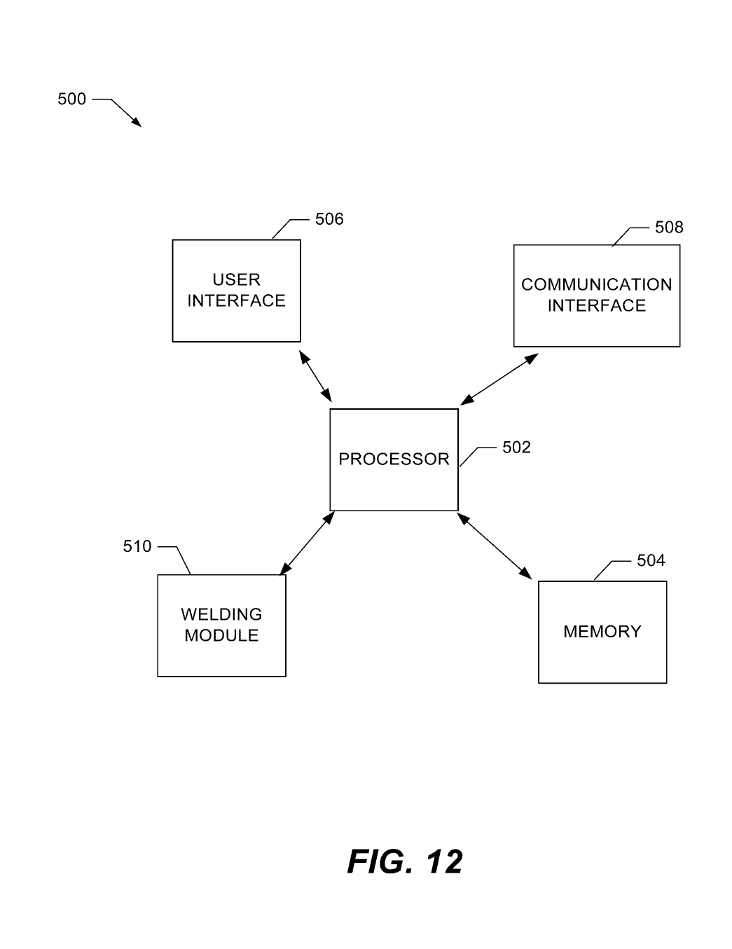

FIG. 12 is a block diagram of an electronic device 500 suitable for use with the described embodiments. In one example embodiment the electronic device 500 may be embodied in or as the controller 214 for the friction stir welding system 200. In this regard, the electronic device 500 may be configured to control or execute the above-described friction stir welding operations.

The electronic device 500 illustrates circuitry of a representative computing device. The electronic device 500 may include a processor 502 that may be microprocessor or controller for controlling the overall operation of the electronic device 500. In one embodiment the processor 502 may be particularly configured to perform the functions described herein. The electronic device 500 may also include a memory device 504. The memory device 504 may include non-transitory and tangible memory that may be, for example, volatile and/or non-volatile memory. The memory device 504 may be configured to store information, data, files, applications, instructions or the like. For example, the memory device 504 could be configured to buffer input data for processing by the processor 502. Additionally or alternatively, the memory device 504 may be configured to store instructions for execution by the processor 502.

The electronic device 500 may also include a user interface 506 that allows a user of the electronic device 500 to interact with the electronic device. For example, the user interface 506 can take a variety of forms, such as a button, keypad, dial, touch screen, audio input interface, visual/image capture input interface, input in the form of sensor data, etc. Still further, the user interface 506 may be configured to output information to the user through a display, speaker, or other output device. A communication interface 508 may provide for transmitting and receiving data through, for example, a wired or wireless network such as a local area network (LAN), a metropolitan area network (MAN), and/or a wide area network (WAN), for example, the Internet.

The electronic device 500 may also include a welding module 510. The processor 502 may be embodied as, include or otherwise control the welding module 510. The welding module 510 may be configured for controlling friction stir welding operations.

The various aspects, embodiments, implementations or features of the described embodiments can be used separately or in any combination. Various aspects of the described embodiments can be implemented by software, hardware or a combination of hardware and software. The described embodiments can also be embodied as computer readable code on a computer readable medium for controlling machining operations. In this regard, a computer readable storage medium, as used herein, refers to a non-transitory, physical storage medium (e.g., a volatile or non-volatile memory device, which can be read by a computer system. Examples of the computer readable medium include read-only memory, random-access memory, CD-ROMs, DVDs, magnetic tape, and optical data storage devices. The computer readable medium can also be distributed over network-coupled computer systems so that the computer readable code is stored and executed in a distributed fashion.

Note that although a particular system for friction stir welding is described above, various other embodiments of systems for friction stir welding may be employed. For example, although use of a friction stir welding tool including a conical pin is described above, various other pins may be employed, such as cylindrical pins. Further, the pin may or may not include threads or flat sections, and the number of threads and dimensions of the pin may vary.

Additionally, the parameters associated with friction stir welding may vary. However, one example embodiment is described below. Rotations per minute of the tool: from about 1500 to about 5000 (e.g., about 4500); Force along the axis of the rotating pin: from about 1500 N to about 4000 N (e.g., about 2500 N); Translational speed of the pin: from about 500 mm/min to about 1600 mm/min (e.g., about 1200 mm/min); Angle of the pin with respect to the joint: from about 0 degrees to about 5 degrees (e.g., about 3 degrees); and Preheat temperature: from about 30 degrees Celsius to about 60 degrees Celsius (e.g., about 45 degrees Celsius).

Although the foregoing disclosure has been described in detail by way of illustration and example for purposes of clarity and understanding, it will be recognized that the above described disclosure may be embodied in numerous other specific variations and embodiments without departing from the spirit or essential characteristics of the disclosure. Certain changes and modifications may be practiced, and it is understood that the disclosure is not to be limited by the foregoing details, but rather is to be defined by the scope of the appended claims.

1. A method, comprising:
positioning a first part and a second part in a fixture with a mating surface of the first part contacting a mating surface of the second part at a joint, wherein the first part defines a first expendable portion at a first end of the joint and a second expendable portion at a second end of the joint, the first expendable portion configured to contact a non-mating surface of the second part to facilitate alignment of the second part with the first part;
compressing the mating surface of the first part against the mating surface of the second part;
inserting a rotating pin into the first expendable portion;
directing the rotating pin along the joint to join the first part to the second part and form an assembly; and
removing the rotating pin from the second expendable portion.

2. The method of claim 1, wherein the second expendable portion is also configured to contact the non-mating surface of the second part and to facilitate alignment of the second part to the first part.

3. The method of claim 2, further comprising:
machining off the first expendable portion and the second expendable portion,
wherein removing the first expendable portion and the second expendable portion comprises machining off the first expendable portion and the second expendable portion.

4. The method of claim 1, further comprising applying a force between the rotating pin and the joint along a rotational axis of the rotating pin.

5. The method of claim 4, wherein directing the rotating pin along the joint comprises directing the rotating pin along a curved surface and directing the rotating pin along a straight surface.

6. The method of claim 5, further comprising decreasing the force when directing the rotating pin along the curved surface relative to the force employed when directing the rotating pin along the straight surface.

7. The method of claim 1, further comprising preheating the first part and the second part.

8. The method of claim 1, further comprising anodizing the assembly.

9. The method of claim 1, wherein the assembly comprises an enclosure for an electronic device.

10. The method of claim 1, wherein the rotating pin comprises a conical pin defining a threaded outer surface comprising one or more flat sections.

11. An enclosure for an electronic device, the enclosure comprising:
an assembly comprising a first part and a second part, the assembly formed by a process comprising:
positioning the first part and the second part in a fixture with a mating surface of the first part contacting a mating surface of the second part at a joint, wherein one of the first part and the second part defines a first expendable portion at a first end of the joint and one of the first part and the second part defines a second expendable portion at a second end of the joint;
compressing the mating surface of the first part against the mating surface of the second part;
inserting a rotating pin into the first expendable portion;
directing the rotating pin along the joint to join the first part to the second part;
removing the rotating pin from the second expendable portion; and
removing the first expendable portion and the second expendable portion.

12. The enclosure of claim 11, wherein the process further comprises applying a force between the rotating pin and the joint along a rotational axis of the rotating pin.

13. The enclosure of claim 12, wherein directing the rotating pin along the joint comprises directing the rotating pin along a curved surface and directing the rotating pin along a straight surface.

14. The enclosure of claim 14, wherein the process further comprises decreasing the force when directing the rotating pin along the curved surface relative to the force employed when directing the rotating pin along the straight surface.

15. A tool configured for friction stir welding, the tool comprising:
a conical pin extending between a first end and a second end, the conical pin defining a threaded outer surface comprising one or more flat sections extending between the first end and the second end; and
a shoe coupled to the second end of the conical pin, the shoe configured to engage a rotatable shaft of a motor.

16. The tool of claim 15, comprising three of the flat sections equally spaced around the threaded outer surface.

17. The tool of claim 15, wherein the conical pin is pointed at the first end.

18. The tool of claim 15, wherein the shoulder defines a planar shoulder proximate the second end of the conical pin.

19. A non-transitory computer readable medium for storing computer instructions executed by a processor in a controller configured to control a friction stir welding system, the non-transitory computer readable medium comprising:
computer code for aligning a mating surface of a first part against a mating surface of a second part at a joint, the first part comprising a first and second expendable portion, the first expendable portion being configured to contact a non-mating surface of the second part to help facilitate alignment between the first part and the second part;
computer code for compressing the first part against the second part at the joint;
computer code for inserting a rotating pin into a first expendable portion at a first end of the joint;
computer code for directing the rotating pin along the joint to join the first part to the second part and form an assembly; and
computer code for removing the rotating pin from a second expendable portion at a second end of the joint.

20. The non-transitory computer readable medium of claim 19, further comprising computer code for machining off the first expendable portion and the second expendable portion.

21. The non-transitory computer readable medium of claim 20, further comprising computer code for applying a force between the rotating pin and the joint along a rotational axis of the rotating pin.

22. The non-transitory computer readable medium of claim 21, wherein computer code for directing the rotating pin along the joint comprises computer code for directing the rotating pin along a curved surface and computer code for directing the rotating pin along a straight surface.

23. The non-transitory computer readable medium of claim 22, further comprising computer code for decreasing the force when directing the rotating pin along the curved surface relative to the force employed when directing the rotating pin along the straight surface.
